(19) United States
(12) Patent Application Publication
(10) Pub. No.: US 2023/0387648 A1
(43) Pub. Date: Nov. 30, 2023

(54) UV LASER SYSTEMS, DEVICES, AND METHODS

(71) Applicant: Pavilion Integration Corporation, San Jose, CA (US)

(72) Inventors: Ningyi LUO, San Jose, CA (US); Jihchuang Robin HUANG, San Jose, CA (US)

(73) Assignee: Pavilion Integration Corporation, San Jose, CA (US)

(21) Appl. No.: 18/031,309

(22) PCT Filed: Oct. 11, 2021
(86) PCT No.: PCT/US21/54452

§ 371 Date: Apr. 11, 2023

Related U.S. Application Data
(60) Provisional application No. 63/090,241, filed on Oct. 11, 2020.

(51) Int. Cl. H01S 3/109; H01S 3/16; H01S 3/0941; H01S 3/06; H01S 3/00; H01S 3/10; G02F 1/355

(52) U.S. Cl. CPC H01S 3/109; H01S 3/1653; H01S 3/0941; H01S 3/0627; H01S 3/0078; H01S 3/0071; H01S 3/10061; G02F 1/3551

(57) ABSTRACT

Devices, systems, and methods for generating ultraviolet lasers are disclosed. Schematics and arrangements of a combination structure implementation that often uses an intra-cavity second harmonic generation (SHG) element and a UV extractor often with a birefringent crystal (BC) to extract the UV light are described and disclosed. A Nonlinear crystal (NLC) may serve as the SHG element and volume Bragg gating (VBG) may be included to control pump light characteristics.

### BACKGROUND

Optically pumped lasers generally fall into two groups: lamp pumped lasers, having some kind of gas discharge lamp, such as an arc lamp or flash lamp, as the pump source and diode-pumped lasers, which are pumped with some kind of laser diodes. Most diode-pumped lasers are considered solid state lasers, that is, they are lasers based on solid-state gain media such as crystals or glasses doped with rare earth or transition metal ions. Diode-pumped solid state lasers have a wide variety of applications. It may be desirable to work with all-solid-state lasers because they can have a robust and compact setup, relatively high wall-plug efficiency and thus low cooling requirements.

Ultra violet (UV) lasers may be optically pumped by lamps or diode-pumped. UV lasers may be utilized in a variety of commercial and industrial applications, including, but not limited to: machining on a micro-scale, engraving of precision tools for stamping or micro-spark erosion, marking of glass and synthetics whereby the surface is not changed in structure or chemical composition, drilling of small holes in a variety of materials for example diesel injectors, and precision cleaning of surfaces, such as with artwork. These examples and applications of UV lasers are non-limiting examples, as there are myriad applications and uses of UV lasers.

### SUMMARY

The present development relates to ultraviolet lasers. More specifically, the present developments relate to an apparatus and method to generate, implement, and/or control ultraviolet lasers using a diode pumped solid state medium and intra-cavity second harmonic conversion.

Another aspect of the current developments the use different combination structures to convert and extract UV light from a pumped light.

One aspect of the current developments is a monolithic ultraviolet (UV) laser that uses an intra-cavity second harmonic generation (SHG) and a birefringent crystal (BC) to extract the UV light.

Another aspect of the current developments is a stable UV laser based on a diode pumped solid state laser and intra-cavity second harmonic conversion.

Another aspect of the current developments is control and adjustment of the polarization of the UV light generated in the device or system.

Another aspect of the current developments is the detecting of the light propagating in the structure, and the selecting and locking of a chosen frequency.

Another aspect of the current developments is the detection and monitoring of the UV light exited from the combination structure.

### BRIEF DESCRIPTION OF DRAWINGS

For a detailed description of exemplary implementations of the developments, reference will now be made to the accompanying drawings in which:

FIG. 1 provides a schematic diagram of an implementation of a UV laser.

FIG. 2 provides a schematic diagram of an alternative implementation of a UV laser.

FIG. 3 provides a schematic diagram of an alternative implementation of a UV laser hereof that integrates a prism and a detector.

FIG. 4 provides a schematic diagram of an implementation of a UV laser that integrates a polarizer prism.

FIG. 5 provides a schematic diagram of a UV laser that includes a waveplate, prism, and a detector.

FIGS. 6A, 6B, and 6C provide diagrams to illustrate how a second harmonic generation crystal can provide wavelength selection.

FIG. 7 provides a schematic diagram of a yet another implementation of a UV laser.

FIG. 8 shows a schematic diagram of a another UV laser hereof.

FIG. 9 provides a schematic diagram of a UV laser that includes an air gap in the cavity.

FIG. 10 provides a schematic diagram of an alternative implementation of a UV laser that includes an air gap in a different position in the cavity.

FIG. 11 shows a schematic diagram of an implementation of a single mode UV laser that incorporates a piezo-electric transducer on the pump diode side and a detector for power feedback.

FIG. 12 provides a graph of how an etalon may be integrated and utilized to select one frequency.

FIG. 13 provides a schematic diagram of an alternative implementation of a single mode UV laser that incorporates a piezo-electric transducer on the NLC side and a detector for power feedback.

FIG. 14 provides a schematic diagram of an alternative implementation that has an air gap in the cavity between the Pr:YLF and the non-linear crystal and the surfaces of the Pr:YLF and non-linear crystal are coated with low loss anti-reflection coatings.

FIG. 15 is a graph of the number of cavity modes supported by laser bandwidth of Praseodymium doped Yttrium Lithium Fluoride (Pr:YLF) emission near 698 nm when the cavity length is 20 mm.

FIG. 16 is a graph of the number of cavity modes supported by laser bandwidth of Praseodymium doped Yttrium Lithium Fluoride (Pr:YLF) emission near 698 nm when the cavity length is 30 mm.

FIG. 17 provides a reference graph that shows experimentally all frequencies within the emission band were lasing simultaneously.

FIG. 18A and FIG. 18B provide diagrams that demonstrate the optical efficiency and pump light absorption of the laser system and/or device may be improved by using volume Bragg grating (VBG) to narrow the diode laser emission bandwidth.

### DETAILED DESCRIPTION

While the developments hereof are amenable to various modifications and alternative forms, specifics hereof have been shown herein by way of non-limitative examples in the drawings and the following description. It should be understood, however, that this is not to limit the inventions hereof to the particular embodiments described. This is instead to cover all modifications, equivalents, and alternatives falling within the spirit and scope of the developments whether described here or otherwise being sufficiently appreciable as included herewithin even if beyond the literal words or figures hereof.

The following discussion is directed to various implementations of the developments hereof. Although one or more of these implementations may be preferred, the implementations disclosed should not be interpreted, or otherwise used, as or for limiting the scope of the disclosure, including the claims. In addition, one skilled in the art will understand that the following description has broad applications, and the discussion of any implementation is only exemplary of that implementation and is not to intimate that the scope of the disclosure, including the claims, is limited to that implementation.

In general, included here are devices, systems and methods for generating, controlling, and employing ultra violet (UV) lasers.

A stable output from a UV laser may be obtained by operating the laser with more than ten cavity frequencies. The average output power of the laser may remain relatively stable because there are many frequencies oscillating inside the cavity.

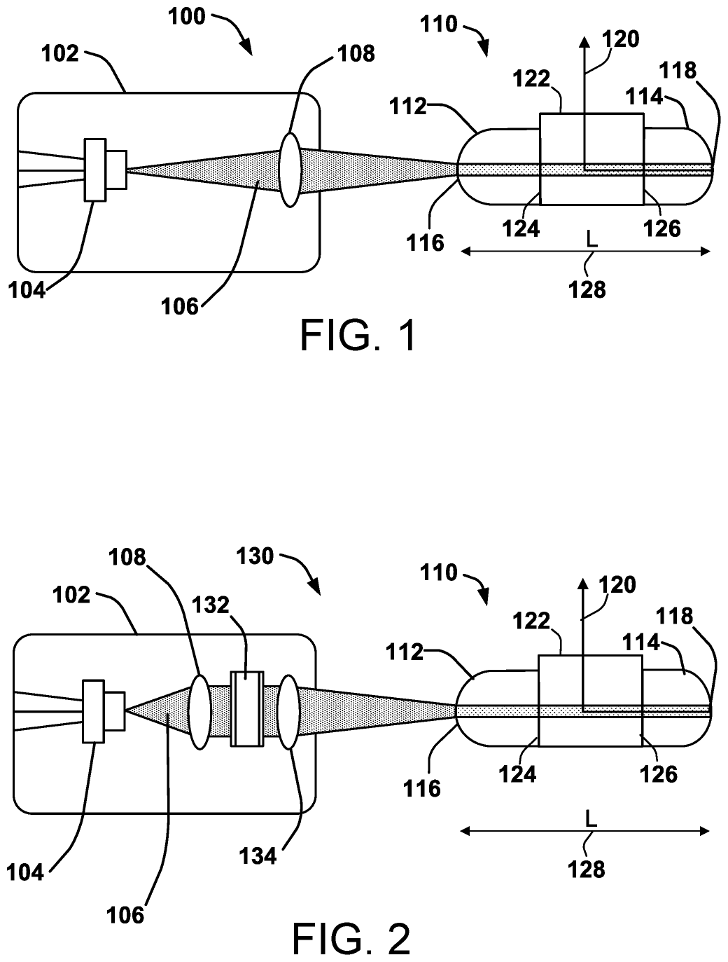

In FIG. 1, a diode-pumped UV laser 100 that utilizes a 444 nm diode-pumped laser source is illustrated. Pump source 102 contains a 444 nm diode laser 104 that produces a diode laser pump light, or pump beam 106 that is sent through a single lens 108 and delivered to the combination structure 110. The pump light 106 enters gain media 112 of the combination structure 110, in this example, the gain medium 112 is a Praseodymium doped Yttrium Lithium Fluoride (Pr:YLF) crystal. The pump light 106 is absorbed by the gain medium 112 and a characteristic lasing wavelength also called fundamental wavelength (FW) associated with the gain medium 112 is produced between cavity mirrors 116, 118. A nonlinear crystal (NLC) 114 that is disposed inside the laser cavity further transforms this FW into UV light 120. The NLC 114 provides second harmonic generation (SHG) and converts the visible light into UV light 120. In one implementation the NLC 114 is Beta Barium Borate Oxide. Other suitable NLCs include Bismuth Borate Oxide (BiBO), walk-off compensated BBO, walk-off compensated BiBO, lithium triborate oxide (LBO), periodically-poled Lithium Niobate (PPLN) and periodically-poled Lithium Tantalate (PPLT). The UV light 120 is extracted from the combination structure 110 by a polarization controller and UV separator 122. The first laser cavity mirror 116 and second laser cavity mirror 118 are disposed on each of the sides of the combination structure 110. In some implementations, the cavity mirrors 116, 118 are fabricated as part of the combination structure 112. All interfaces between the laser cavity mirrors, i.e. the surface of the gain medium 112 abutting, adjacent and in contact with surface of the UV extractor and/or birefringent crystal 124, and the surface of the birefringent crystal abutting, adjacent and in contact with the surface of the NLC 126 are optically bonded.

Optical bonding refers to connecting and bonding components of the combination structure without using adhesives. The components to be bonded together are maintained in optical contact during the bonding process. Both similar and dissimilar crystal and glasses may be bonded together through optical bonding. There are a variety of techniques of establishing, obtaining, and maintaining the optical contact but these techniques all result in an interface that is bonded mainly through Van der Waals forces. Further, optical bonding may be achieved by application of pressure, capillary adhesion, or by bringing two clean and dry surfaces into intimate contact. Optical bonding, that is, adhesive-free bonding, may overcome issues such as beam distortion and performance degradation. Thus, optical bonding may result in high quality bonded interfaces that are both strong and optically transparent.

Mirror 116 may in some instances be referred to as an inlet mirror, indicating that the pump light 106 enters the combination structure 110 through this mirror. Mirror 116 may be flat or curved, but provides a reflecting surface for containing and resonating the light and/or fundamental wavelength in the combination structure 110. Mirror 116 may be fabricated with the gain media or optically bonded to the gain media. Mirror 118 may in some instances be referred to as the second mirror. Again, mirror 118 may be flat or curved, yet providing a reflecting surface for containing and resonating the light and/or fundamental wavelength in the combination structure 110.

The combination structure 110 has a length (L) 128 which may range from less than about 10 mm to more than about 2 m. In preferred implementations, the combination structure may have a length of about 20 mm, 30 mm, or 40 mm, to keep it relatively compact. In some implementations a combination structure may be a monolithic or unitary or composite structure.

An alternative implementation of a diode-pumped UV laser 130 shown in FIG. 2 includes a lens 108, a volume Bragg grating (VBG) 132, and a second lens 134. The VBG 132 is positioned in between the first lens 108 and the second lens 134. Using two lenses and a VBG may provide the ability to control some of the pump light characteristics. Accordingly, the optical efficiency of the laser may be improved by maximizing the pump light absorption by using a volume Bragg grating (VBG) 132 to narrow down the diode laser emission spectrum where the gain medium (or gain crystal) has an absorption bandwidth narrower than that of the pump diode emission. When Pr:YLF is used as the gain medium, the absorption near 444 nm has a bandwidth around 1 nm full width half maximum (FWHM). Typically, 444 nm multimode (MM) blue diode laser has emission bandwidth of 2-4 nm. Thus, adding a VBG 132 between imaging lenses 108, 134 enables one to narrow the emission spectrum and control the central wavelength. Other structures and methods for selecting and/or locking the wavelength include using a fiber Bragg grating (FBG) and adjusting the length of the gain media. These alternative structures and methods are discussed in more detail, below. In one aspect, the VBG 132 may be utilized and implemented to match the diode emission spectrum to the absorption of the gain media.

Returning to FIG. 2, pump source 102 contains a 444 nm diode laser 104 that produces a diode laser pump light, or pump beam 106 that is sent through a first lens 108, a VBG 132, and a second lens 134, and delivered to the combination structure 110, having a length (L) 128. The pump light 106 enters gain media 112 of the combination structure 110, in this example, the gain medium is a Praseodymium doped Yttrium Lithium Fluoride (Pr:YLF) crystal. The pump light is absorbed by the gain medium and is converted into one of the characteristic wavelength also called fundamental wavelength associated to the gain medium between cavity mirrors 116, 118. A nonlinear crystal (NLC) 114 that is disposed inside the laser cavity further transforms this FW into UV light. The NLC 114 provides second harmonic generation (SHG) and converts the visible light into UV light. The UV light 120 is extracted from the combination structure 110 by a polarization controller and UV separator 122 which is disposed between the gain media 112 and NLC 114. Mirrors 116 and 118 are disposed on each of the sides of the combination structure 110. The cavity mirrors 116, 118 are fabricated as part of the combination structure 112. Again, the interfaces 124, 126 are optically bonded. The UV laser 130 of FIG. 2, illustrates how the addition of a VBG and a second lens provide the capability of maximizing the pump light absorption by narrowing down the diode laser emission bandwidth to match with the gain medium's absorption spectrum.

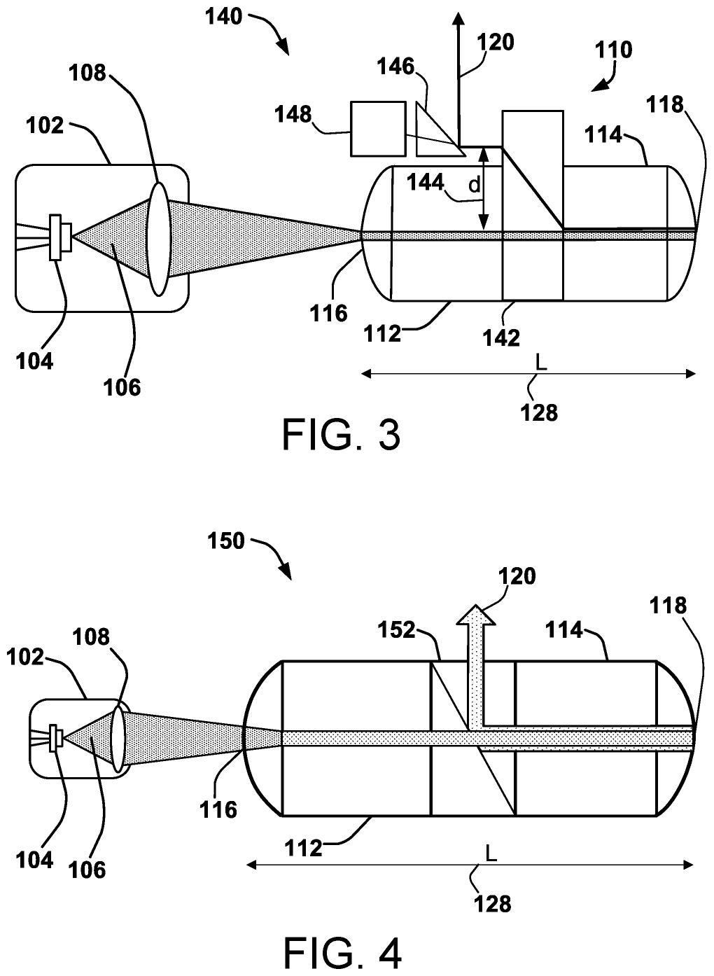

An alternative implementation of a UV laser 140 of the current developments is illustrated in FIG. 3, which demonstrates how a birefringent crystal (BC) 142 may be disposed between the gain media 112 and NLC 114. The BC 142 may in some implementations be α-BBO. Other materials, such as MgF₂, LiNbO₃, alpha-BBO, quartz, calcite, and YVO₄ may be used in some implementations; however, characteristics such as absorption, walk-off angle, and optical bonding compatibility may be considered as they relate to using such materials as a suitable BC. As shown in FIG. 3, a diode-pumped UV laser 140 utilizes a pump source 102 that has a 444 nm diode laser 104 that produces a diode laser pump light 106 that is propagated through a single lens 108 and delivered to a combination structure 110; the combination structure 110 having a length (L) 128. The pump light 106 enters gain media 112 of the combination structure 110, in this example, the gain medium is a Praseodymium doped Yttrium Lithium Fluoride (Pr:YLF) crystal. The FW is generated by the gain medium 112 and the light path includes a nonlinear crystal (NLC) 114 that is disposed inside the laser cavity. The NLC 114 provides second harmonic generation (SHG) and converts the visible light into UV light. The UV light 120 is extracted from the combination structure 110 by a BC 142. Laser cavity mirrors 116 and 118 are disposed on each of the sides of the combination structure 110. The cavity mirrors 116, 118 are fabricated as part of the combination structure 110. It should be noted that the BC 142 extends or protrudes above the rest of combination structure 110. Depending on the components used and employed in the combination structure 110, the UV extractor may extend or protrude beyond the other portions of the body of the combination structure, for example see FIGS. 1, 2, 5, 7, 8, 9, 10, 11, 13, and 14, which are non-limiting examples of this aspect. However, in some implementations, the UV extractor does not extend further than the rest of the body of the combination structure 110, as in FIG. 4, which is a non-limiting example of this aspect.

In FIG. 3, where the laser gain media used is Pr:YLF lasing at 698 nm, the SHG (UV) wavelength is 349 nm and is in a polarization mode of e-wave versus o-wave of 698 nm inside the BC. The o-wave remains aligned inside the cavity whereas the e-wave walks off from the o-wave at an angle of 4.3° inside the α-BBO crystal. After 10 mm of traveling inside the α-BBO crystal, the separation between 698 nm and 349 nm is a distance (d) 144 of 0.8 mm. The BC 142 is designed and fabricated to be larger than the gain media 112 to allow the deviated UV light to exit the combination structure as shown in FIG. 3. Moreover, the combination structures of FIGS. 3, 5, 7, 8, 9, 10, and 11 demonstrate that the BC may be made to be larger than the respective gain media to allow the deviated UV light to exit the combination resonator. Furthermore, the length and shape of the BC may be changed to optimize the distance (d) 144. A partially transmitting mirror or prism 146 is positioned outside, but in close proximity of the combination structure 110 to receive the deviated UV light 120 as it exits the combination structure. A UV power detector 148 is positioned behind the partially transmitting mirror 146. The UV power detector 148 is used to monitor and detect the power of the UV light that is propagating and exiting from the combination structure 110.

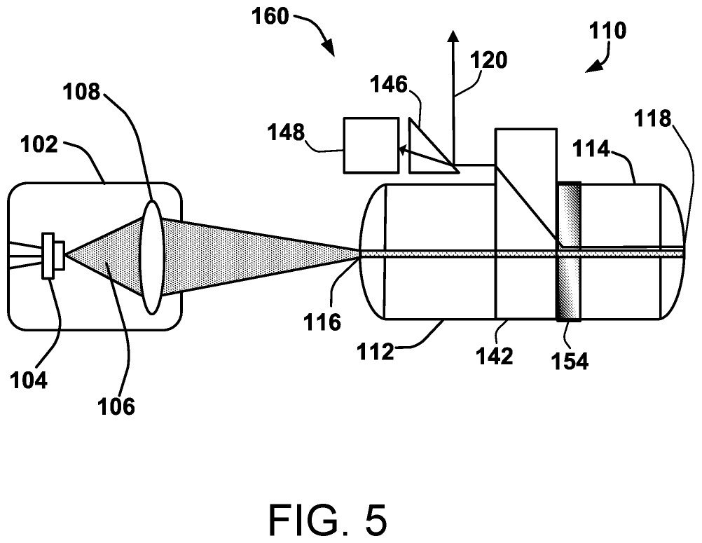

FIGS. 1, 2, and 3 provide examples of combination Type I SHG cavities. SHG occurs in three types for critical phase matching. In Type 0 SHG, two photons having extraordinary polarization with respect to the crystal will combine to form a single photon with double the frequency/energy in extraordinary polarization. The periodically poled NLC belongs to this type of phase matching category. In type I SHG, the UV light that is generated has polarization perpendicular to the polarization of the FW. Furthermore, in Type I SHG two photons having ordinary polarization with respect to the crystal will combine to form one photon with double the frequency in extraordinary polarization. In Type II SHG, two photons having orthogonal polarizations will combine to form one photon with double the frequency in either ordinary or extraordinary polarization. For periodically poled material, an additional waveplate (WP) is inserted between the NLC and BC to rotate the UV polarization 90° but keep the FW polarization unchanged, as shown in FIG. 5, discussed in more detail below.

FIG. 4 provides another implementation of a diode-pumped UV laser 150. In FIG. 4, a polarizing prism (PP) 152, such as a Glan-Taylor prism, is disposed between a gain media 112 and NLC 114. As shown in FIG. 4, a diode-pumped UV laser 150 utilizes a pump source 102 that has a 444 nm diode laser 104 that produces a diode laser pump light 106 that is propagated through a single lens 108 and delivered to a combination structure 110; the combination structure 110 having a length (L) 128. The pump light 106 enters gain media 112 of the combination structure 110, in this example, the gain medium is a Praseodymium doped Yttrium Lithium Fluoride (Pr:YLF) crystal. The pump light is absorbed by the gain medium 112 and is converted into FW. A nonlinear crystal (NLC) 114 that is disposed inside the laser cavity provides second harmonic generation (SHG) and converts the visible light into UV light. The UV light 120 is extracted from the combination structure 110 by a polarizing prism (PP) 152. Laser cavity mirrors 116 and 118 are disposed on each of the sides of the combination structure 110. The cavity mirrors 116, 118 are fabricated as part of the combination structure 110. Again, all the interfaces between the first mirror 116, gain media 112, polarizing prism 152, NLC 114, and second mirror 118 are optically bonded, as described above. As further shown in FIG. 4, the UV light is deflected at a large angle from the cavity path and exits from the combination structure.

The diode-pumped UV laser 160 in FIG. 5 demonstrates that when a periodically poled material, such as periodically-poled Lithium Niobate (PPLN) and periodically-poled Lithium Tantalate (PPLT), is used for the NLC 114, a waveplate (WP) 154 is inserted between the NLC 114 and the BC 142. The WP 154 rotates the UV polarization 90° but maintains the FW polarization. Thus, in FIG. 5, a pump source 102 has a diode laser 104 that produces a diode pump light 106 that is directed though a lens 108 and directed in to a combination structure 110. The pump light 106 enters gain media 112 of the combination structure 110, in this example, the gain medium is a Praseodymium doped Yttrium Lithium Fluoride (Pr:YLF) crystal. The pump light is absorbed by the gain medium 112 and is converted into FW. A nonlinear crystal (NLC) 114 that is disposed inside the laser cavity provides second harmonic generation (SHG) and converts the visible light into UV light. In FIG. 5, the NLC 114 used is a periodically poled material, such as PPLN or PPLT, and thus a WP 114 is placed between the NLC 114 and α-BBO BC 142. The UV light 120 is extracted from the combination structure 110 by the BC 142. Laser cavity mirrors 116 and 118 are disposed on each of the sides of the combination structure 110. The cavity mirrors 116, 118 are fabricated as part of the combination structure 110. Again, all the interfaces between the first mirror 116, gain media 112, BC 142, WP 154, NLC 114, and second mirror 118 are optically bonded, as described above.

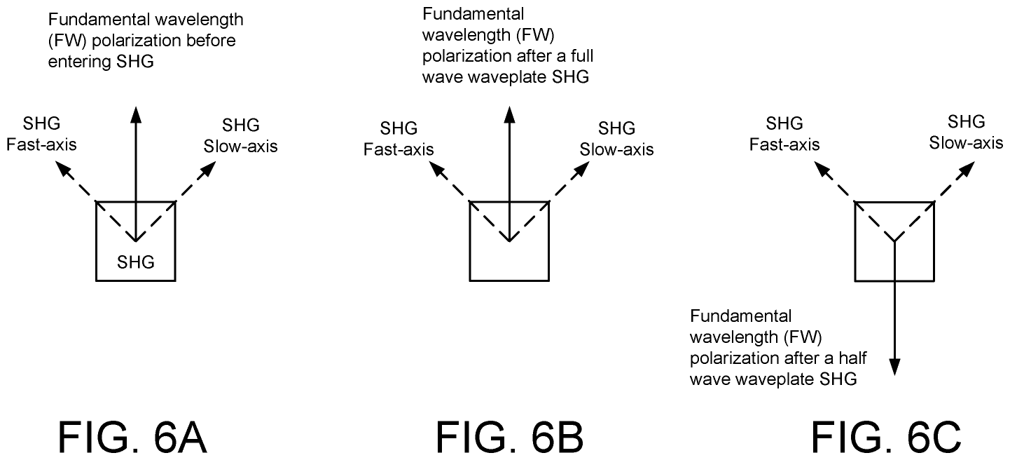

In addition to its wavelength conversion properties, the NLC of Type 1 and Type II SHG crystal can provide wavelength selection by using its birefringent property. FIGS. 6A, 6B, and 6C provides arrangements that demonstrate that the polarization of the FW is about 45° relative to the fast axis and slow axis of the NLC. FIG. 6A shows the FW polarization before entering the NLC. FIG. 6B shows the NLC behavior like a full wave waveplate by having FW polarization remain the same after passing through the NLC. FIG. 6C shows the NLC behavior like a half wave waveplate by having the FW polarization change in direction (180° as compared to FIG. 6A) after passing through the NLC. The NLC may be temperature controlled to be a half wave or a full wave waveplate of the FW, such that the FW is resonant between the first mirror (M1) and second mirror (M2) of the combination structure, and thus other wavelengths may be suppressed. The UV light has a polarization collinear with the Fast-axis or Slow-axis depending on the type of SHG crystal used. FIG. 5, described above, provides an implementation in which a waveplate (WP) 154 is installed to rotate the polarization of the UV light 120 to be perpendicular to the FW yet maintain the FW polarization as unchanged.

In many implementations, a stable UV laser is enhanced by using a combination laser structure that has no air gap interfaces inside the cavity. Air to optics interfaces may be susceptible to damage when UV light is present. Minimizing the number of interfaces where UV light makes transition between air and optical components may help ensure laser reliability. Thus, one aspect of the current developments may include fabricating the cavity mirrors, see mirrors 116, 118 as in FIG. 1, inter alia, as part of the combination structure. Moreover, one aspect of several implementations described herein is that all of the interfaces between the mirrors, gain media, NLC, BC, WP, and other elements are optically bonded.

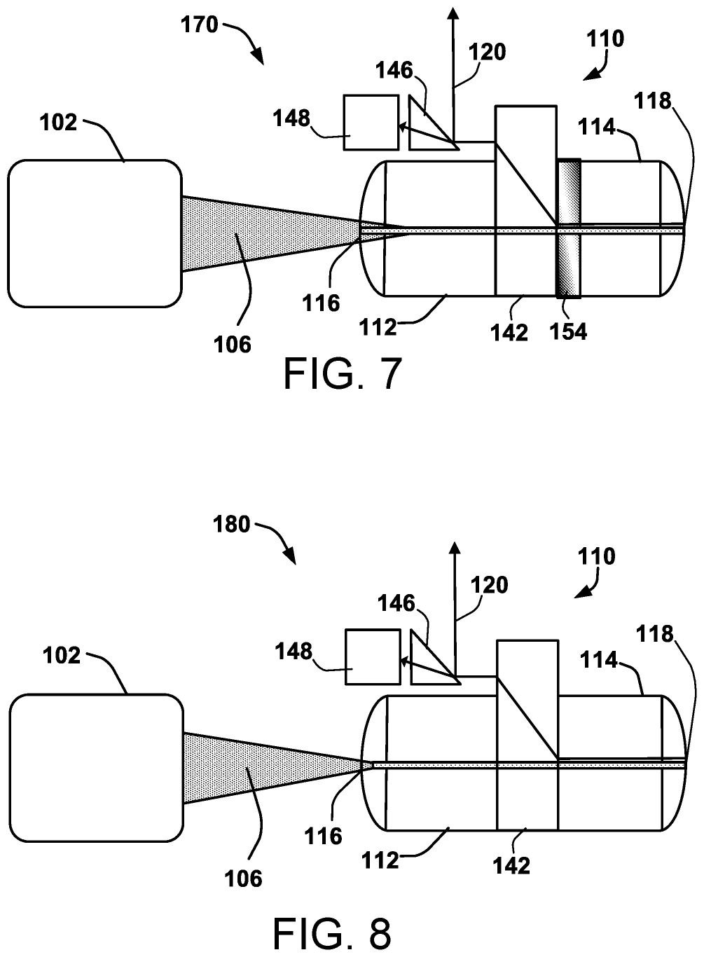

The diode-pumped UV laser 170 in FIG. 7 shows a schematic diagram when a non-periodically poled material, such as Beta Barium Borate Oxide, Bismuth Borate Oxide (BiBO), walk-off compensated BBO, walk-off compensated BiBO, lithium triborate oxide (LBO), is used for the NLC 114, a waveplate (WP) 154 is inserted between the NLC 114 and the BC 142. The WP 154 rotates the UV polarization 90° but maintains the FW polarization. Thus, in FIG. 7, a pump source 102 produces a pump light 106 that is directed in to a combination structure 110. The pump light 106 enters gain media 112 of the combination structure 110, in this example, the gain medium is a Praseodymium doped Yttrium Lithium Fluoride (Pr:YLF) crystal. The pump light is absorbed by the gain medium 112 and is converted into FW. A nonlinear crystal (NLC) 114 that is disposed inside the laser cavity provides second harmonic generation (SHG) and converts the visible light into UV light. In FIG. 7, a WP 154 may be placed between the NLC 114 and α-BBO BC 142. The UV light 120 is extracted from the combination structure 110 by the BC 142. Laser cavity mirrors 116 and 118 are disposed on each of the sides of the combination structure 110. The cavity mirrors 116, 118 are fabricated as part of the combination structure 110. Again, all the interfaces between the first mirror 116, gain media 112, BC 142, WP 154, NLC 114, and second mirror 118 are optically bonded, as described above.

FIG. 8 provides another example of a diode-pumped UV laser. FIG. 8, demonstrates how a birefringent crystal (BC) 142 may be disposed between the gain media 112 and NLC 114. The BC 142 may in some implementations be α-BBO. As shown in FIG. 8, a pump source 102 produces a diode laser pump light 106 that is propagated and delivered to a combination structure 110. The pump light 106 enters gain media 112 of the combination structure 110, in this example, the gain medium is a Praseodymium doped Yttrium Lithium Fluoride (Pr:YLF) crystal. The pump light is absorbed by the gain medium 112 and is converted into FW. A nonlinear crystal (NLC) 114 that is disposed inside the laser cavity provides second harmonic generation (SHG) and converts the visible light into UV light. The UV light 120 is extracted from the combination structure 110 by a BC 142. Laser cavity mirrors 116 and 118 are disposed on each of the sides of the combination structure 110. The cavity mirrors 116, 118 are fabricated as part of the combination structure 110. A partially transmitting mirror or prism 146 is positioned outside, but in close proximity of the combination structure 110 to receive the deviated UV light 120 as it exits the combination structure 110. A UV power detector 148 is positioned behind the partially transmitting mirror or prism 146. The UV power detector 148 is used to monitor and detect the power of the UV light 120 that is propagated and emitted from the combination structure 110.

Another aspect of the current developments is that the laser structure may be housed inside a temperature stabilized enclosure.

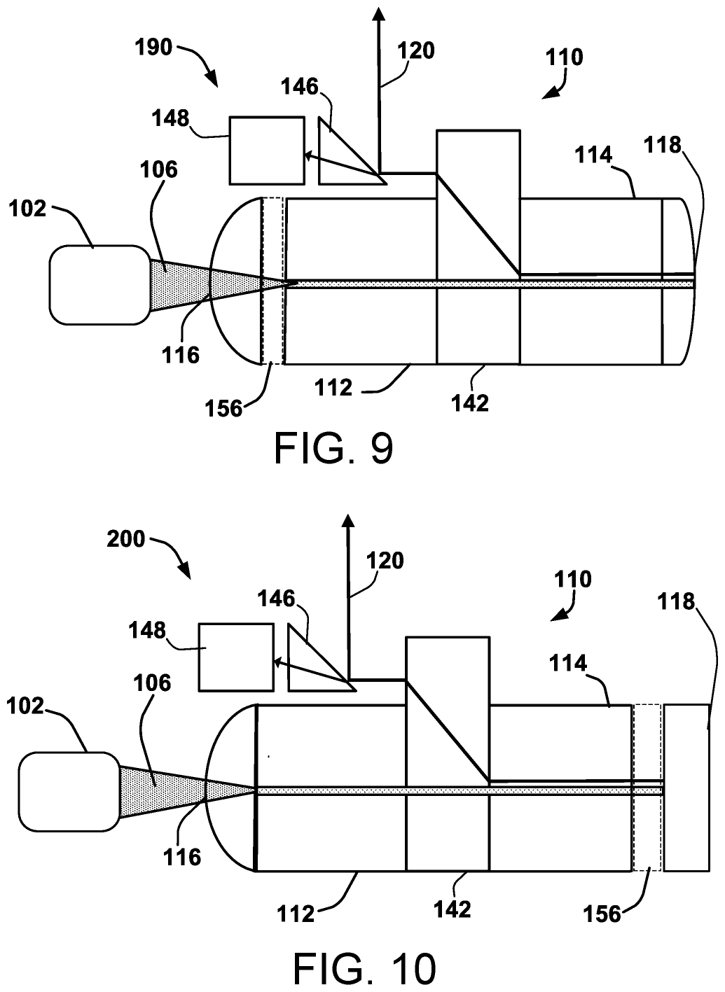

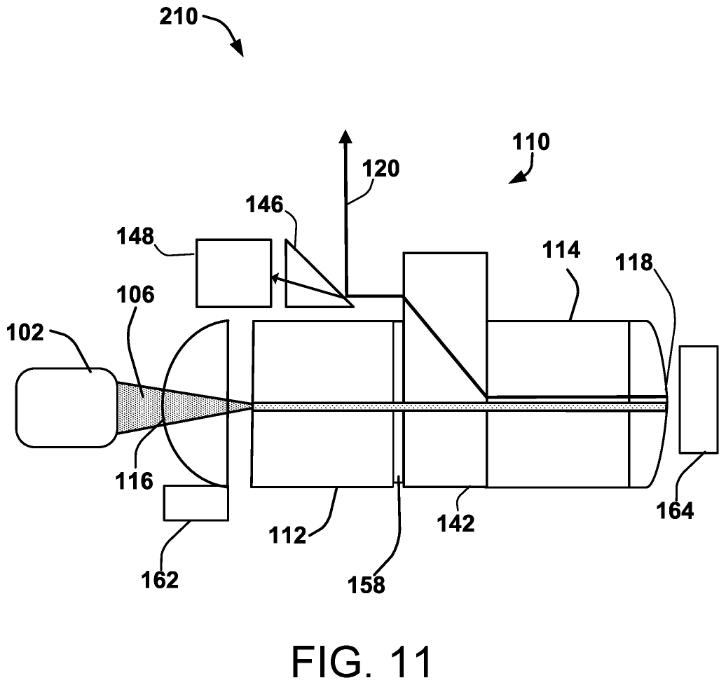

In several alternative implementations, such as those illustrated in FIGS. 9, 10, and 11, the combination structure 110 includes an air gap inside the cavity. FIGS. 9 and 11 demonstrate that an air gap may be between the first mirror and the Py:YLF crystal, or other gain media. In this aspect, the first mirror 116 may be adjustable in relation to the combination structure 110. In this implementation, the adjustability of the first mirror 116 may provide the added benefit of allowing the laser to be aligned easier. In this arrangement, the UV light is produced and extracted through the use of the NLC and BC; however, the extracted UV light does not go through any air gap inside the cavity.

Thus, FIG. 9 demonstrates that a pump source 102 producing and providing a pump light 106 that is directed toward a combination structure 110. However, in this implementation the first mirror 116 has an air gap 156 (that is defined by the dashed-line area as shown in FIG. 9) between the first mirror and the first component, the gain media 112, of the combination structure 110. The pump light 106 is allowed to resonate in the combination structure 110, as the NLC 114, here comprised of β-BBO, acts as a SHG. The UV light 120 is extracted by the BC 142, here α-BBO crystal. It should be noted that in this implementation, the first mirror 116 is adjustable and thus allows for easier alignment but also may allow for the size of the cavity to be varied; however, the extracted UV light does not go through the air gap inside the cavity. Again, a partially transmitting mirror or prism 146 is positioned outside, but in close proximity of the combination structure 110 to receive the deviated UV light 120 as it exits the combination structure. A UV power detector 148 is positioned behind the partially transmitting mirror or prism 146. The UV power detector 148 is used to monitor and detect the power of the UV light that is propagating and exiting from the combination structure 110. FIG. 9 illustrates an alternative UV laser 190 that demonstrates that having an adjustable first mirror 116 may provide benefits of providing the ability to align the laser and also change the length of the cavity, while maintaining the ability to extract UV light while limiting the exposure of UV light of air to optical component transitions.

FIG. 10, provides yet another non-limiting example of how an air gap 156 may be incorporated in to a UV laser 200. In this implementation, the air gap 156 is between the NLC 114 and second mirror 118. In FIG. 10, mirror 118 is free to adjust and this adjustability may also allow the size of the resonator to be adjusted and may also allow the laser to be easily aligned. In FIG. 10, a pump source 102 produces and provides a pump light 106 that is directed toward a combination structure 110. However, in this implementation an air gap 156 (that is defined by the dashed-line area as shown in FIG. 10) exists between the NLC 114 and the second mirror 118. The pump light 106 is allowed to resonate in the combination structure 110, as the NLC 114, here comprised of β-BBO, acts as a SHG. The UV light 120 is extracted by the BC 142, here α-BBO crystal. It should be noted that in this implementation, the second mirror 118 is adjustable and thus allows for easier alignment but also may allow for the size of the cavity to be varied. Again, a partially transmitting mirror or prism 146 is positioned outside, but in close proximity of the combination structure 110 to receive the deviated UV light 120 as it exits the combination structure 110. A UV power detector 148 is positioned behind the partially transmitting mirror or prism 146. The UV power detector 148 is used to monitor and detect the power of the UV light that is propagated and emitted from the combination structure 110.

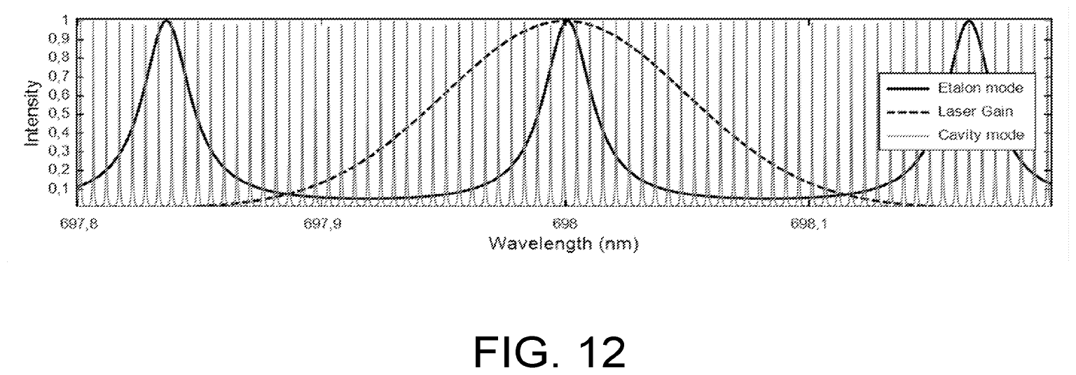

FIG. 11 provides yet another alternative implementation of a UV laser 210. With the first mirror 116 free to adjust and the second mirror 118 fixed, the laser can be made to emit only one frequency by adding an intra-cavity etalon (E) 158. Further, the first mirror 116 may be mounted on a piezo-electrical transducer (PZT) 162 that uses the power feedback signal from the detector 164 to select and/or lock in one frequency. FIG. 12 provides a graph demonstrating how the power feedback signal may be selected in one frequency.

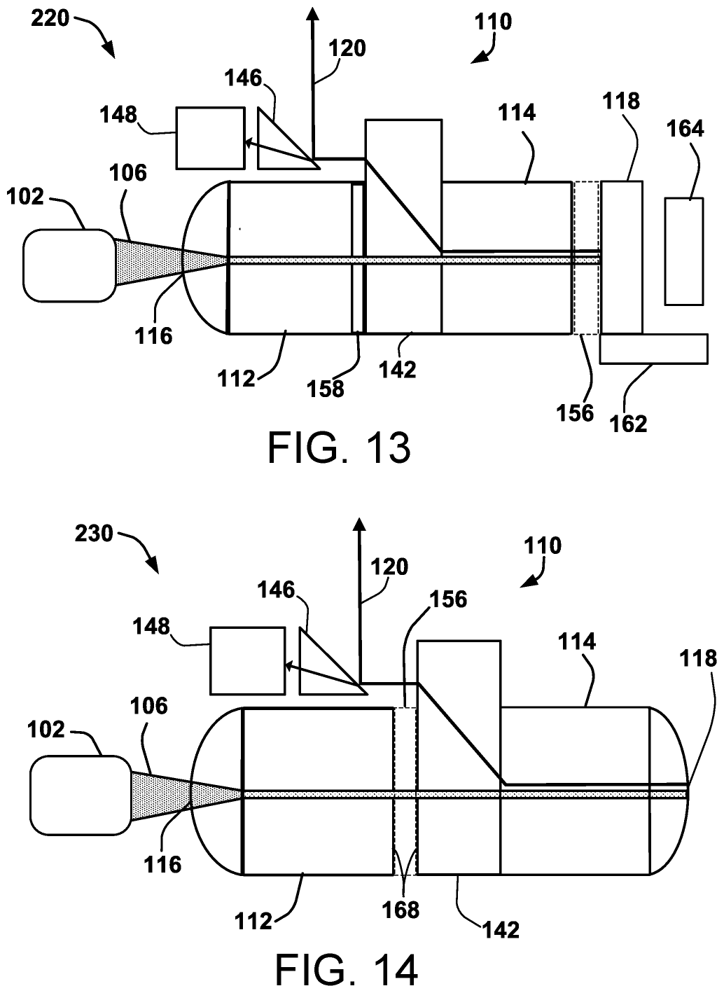

FIG. 13 provides yet another alternative implementation of a UV laser. 220. With the second mirror 118 free to adjust and the first mirror 116 being fixed in place, the laser can be made to emit only one frequency by adding an intra-cavity etalon 158. The second mirror 118 is mounted on a PZT 162 and uses the power feedback signal, from a detector 164 to select and/or lock in one frequency. Thus, FIG. 13 provides an implementation of UV laser 220 with an optional air gap 156. In this implementation, a pump source 102 provides a pump light 106 directed toward and aligned toward an entry way on mirror 116. The light 106 passes through a gain media 112, an intra-cavity etalon 158, an NLC 114, and an air gap 156 and is reflected back by a mirror 118 that is disposed at the end of the cavity. Mirror 118 is communicably connected and in some instances mounted on a PZT 162 which uses the power feedback signal to select and/or lock in one frequency. In this implementation, mirror 118 is free to adjust and thus a single mode UV laser is made operable by adding an intra-cavity etalon 158 or VBG and a PZT 162 to mirror 118.

FIG. 14 provides yet another alternative implementation of a UV laser 230. In this implementation, an optional air gap is placed between the Pr:YLF, gain media 112 and the NLC 114 as shown in FIG. 14. In this arrangement, the surfaces between gain media 112 (Pr:YLF) and NLC 114 are coated with a low loss anti-reflection coating 168. In this implementation of a UV laser 230, shown in FIG. 14, a pump source 102 provides a pump light 106 that is directed to a combination structure 110. The combination structure 110 is defined by mirrors 116, 118 that are located and disposed at opposite ends of the combination structure 110. The pump light 106 passes through the gain media 112, air gap 156, NLC 114, and is reflected by mirror 118. After resonating in the combination structure 110, the UV light 120 is separated by a BC 142 and exited from the structure towards a prism 146. A UV power detector 148 is positioned behind the partially transmitting mirror 146. The UV power detector 148 is used to monitor and detect the power of the UV light that is propagating and exiting from the combination structure 110.

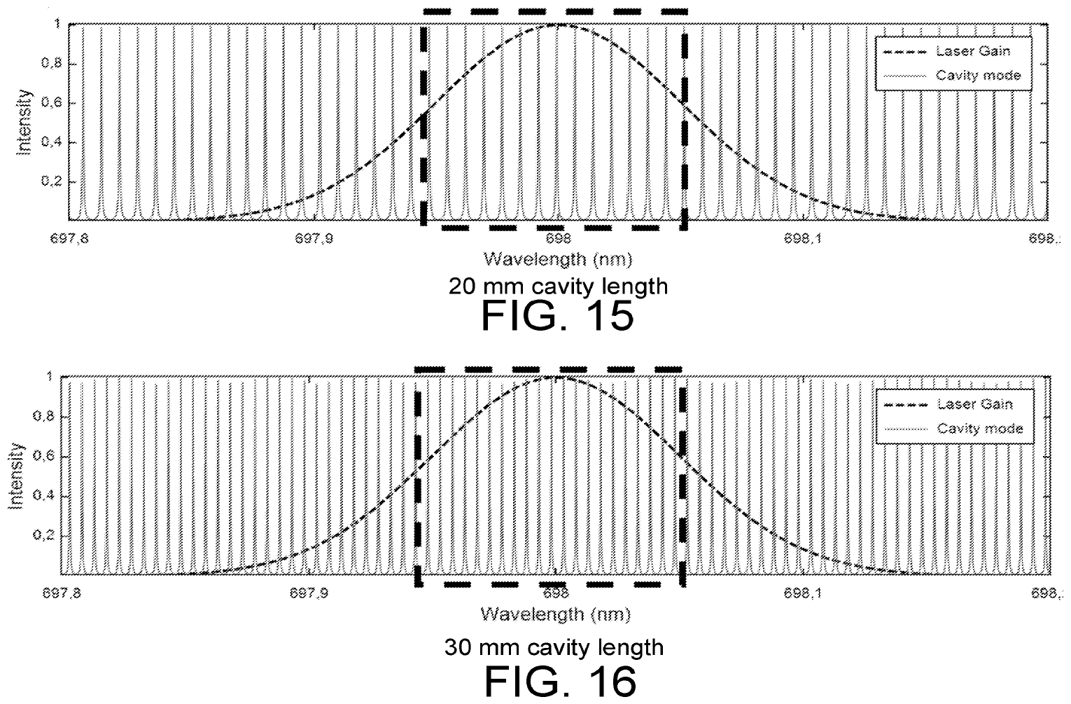

FIG. 15 and FIG. 16 provide examples of graphs that show the number of cavity modes that are supported by laser bandwidth of Praseodymium doped Yttrium Lithium Fluoride (Pr:YLF) emission near 698 nm. FIG. 15 shows the cavity mode supported for a 20 mm cavity length. FIG. 16 shows the cavity mode supported for a 30 mm cavity length. FIG. 15 provides a graph of a 20 mm long cavity comprising a 6 mm Pr:YLF and 14 mm BBO (10 mm α-BBO and 4 mm β-BBO) has FSR=4.35 GHz. Pr:YLF emission at 698˜0.1 nm bandwidth can support ˜14 modes as shown in FIG. 15. FIG. 16 provides a graph of a 30 mm cavity comprising a 6 mm Pr:YLF and 24 mm BBO (10 mm α-BBO and 14 mm β-BBO) has FSR=2.84 GHz that allows ˜21 modes. In another implementation, a 40 mm long cavity comprising a 6 mm Pr:YLF and 34 mm BBO (10 mm α-BBO and 14 mm β-BBO) has FSR=2.84 GHz that allows ˜29 modes.

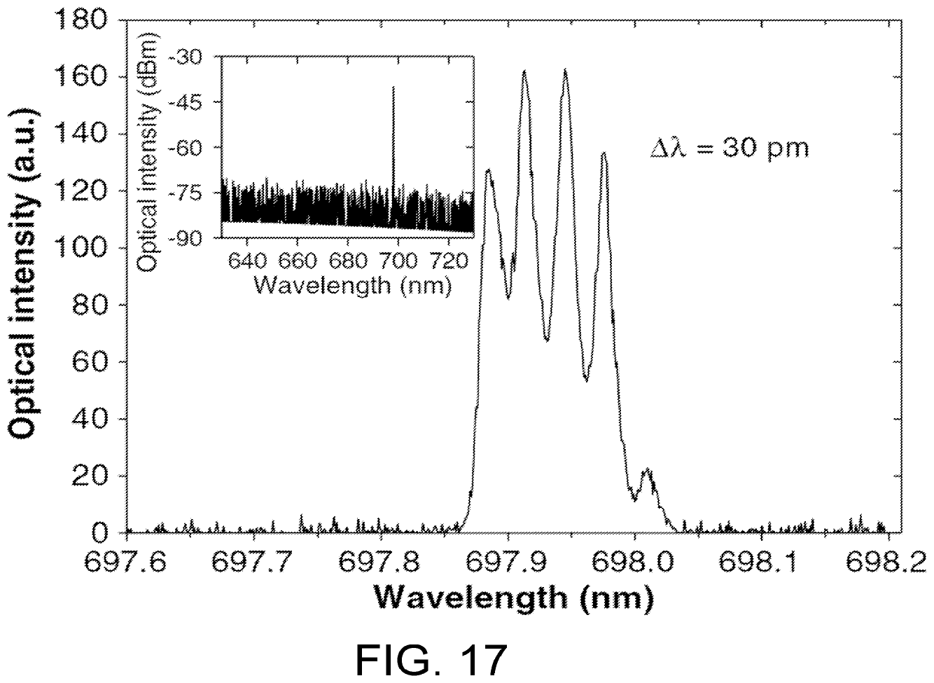

FIG. 17 provides a graph that shows experimentally all frequencies within the emission band were lasing simultaneously. The wavelength and optical intensity of a possible implementation is shown. Thus, a stable output from a UV laser may be obtained by operating the laser with more than ten cavity frequencies. The average output power of the laser may remain relatively stable because there are many frequencies oscillating inside the cavity.

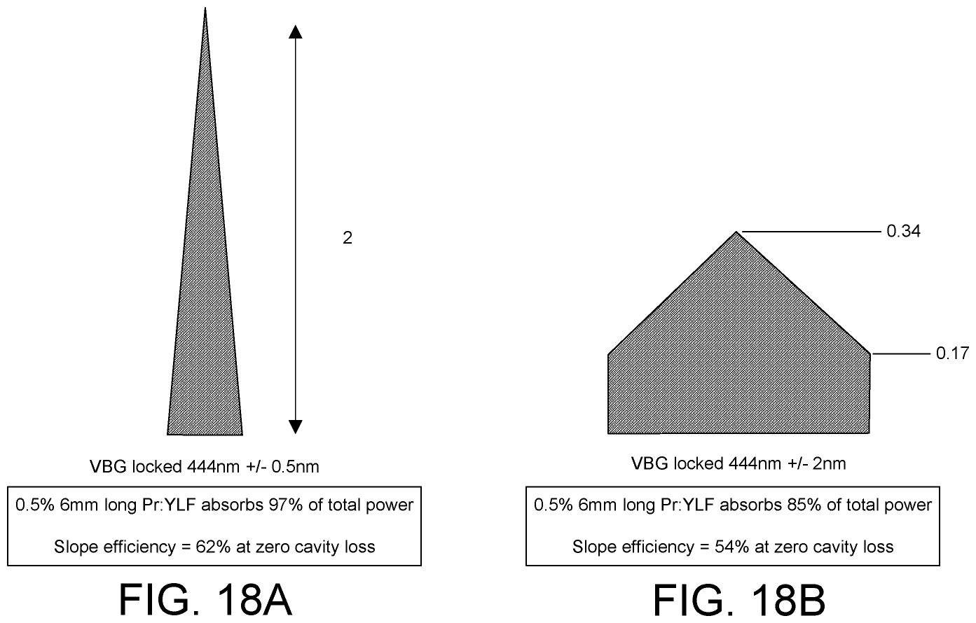

Higher optical efficiency may be achieved by maximizing the pump light absorption. One aspect for achieving higher optical efficiency may be realized by adding a VBG to narrow the diode laser emission spectrum. FIGS. 18A and 18B demonstrate that narrowing down the diode laser emission spectrum improves the absorption by 12%. For example, in FIG. 18A, a VBG locked 444 nm+/−0.5 nm, a 0.5% 6 mm long Pr:YLF absorbs 97% of total power with a slope efficiency=62% at zero cavity loss. In FIG. 18B, a VBG locked at 444 nm+/−2 nm, a 0.5% 6 mm long Pr:YLF absorbs 85% of total power with a slope efficiency=54% at zero cavity loss. For a 479 nm pump source the absorption cross section is twice of 444 nm but much narrower ˜0.5 nm FWHM. For 0.5% 6 mm long Pr:YLF absorbs nearly 100% of total power slope efficiency=68% relative to the power of full spectrum.

The above discussion is illustrative of the principles and various implementations of the present developments. Numerous variations, ramifications, and modifications of the basic concept which have not been described may become apparent to those skilled in the art once the above disclosure is fully appreciated. Therefore, the above description should not be taken as limiting the scope of the inventions, which is defined by the appended claims.

What is claimed is:

1. A method, device or system as described herein.

2. A device or system for generating a UV laser, the device or system comprising:
a source of light;
a combination structure comprising:
two or more mirrors;
a gain media;
a non-linear crystal disposed to be a secondary harmonic generator (SHG);
a UV extractor;
the combination structure being disposed that the light from the source of light enters at a first mirror of the two or more mirrors, passes through the gain media, then passes through the non-linear crystal and the second of the two or more mirrors to and through the UV extractor to produce UV light.

3. A device or system according to any of the prior claims; the UV extractor being:
a polarization controller and
one of:
a UV separator, or
a birefringent crystal,
the UV extractor separating the UV light from the source light.

4. A device or system according to any of the prior claims:
the two or mirrors, the gain media, the non-linear crystal and the UV extractor forming a combination structure having a length (L).

5. A device or system according to any of the prior claims:
the gain media comprising Pr:YLF.

6. A device or system according to any of the prior claims:
the non-linear crystal comprising a material selected from Beta Barium Borate Oxide, Bismuth Borate Oxide (BiBO), walk-off compensated BBO, walk-off compensated BiBO, lithium triborate oxide (LBO) for second harmonic generation.

7. A device or system according to any of the prior claims, the light source further comprising a pump source.

8. A device or system according to claim 7, the pump source having one or more of:
a diode pumped laser,
a first lens,
a volume Bragg grating, and
a second lens.

9. A device or system according to claim 8, the pump source further comprising a 444 nm diode laser.

10. A device or system according to any of the prior claims, the UV extractor including a polarization controller and UV separator.

11. A device or system according to any of the prior claims, including one or both of:
the non-linear crystal being a α-Barium Borate Oxide non-linear crystal for second harmonic generation, and
the UV extractor being a β-Barium Borate Oxide birefringent crystal.

12. A device or system according to any of the prior claims; including one or both of:
the non-linear crystal being a β-Barium Borate Oxide non-linear crystal for second harmonic generation; and
the UV extractor being a polarizer prism for separating UV light from the light source.

13. A device or system according to any of the prior claims; including:
the non-linear crystal selected from the group of periodically-poled Lithium Niobate (PPLN) and periodically-poled Lithium Tantalate (PPLT).

14. A device or system according to any of the prior claims; including one or both of a waveplate; and
a α-Barium Borate Oxide birefringent crystal.

15. A device or system according to any of the prior claims,
the non-linear crystal selected from the group of Bismuth Borate Oxide (BiBO), walk-off compensated BBO, walk-off compensated BiBO, and lithium triborate oxide (LBO).

16. A device or system according to any of the prior claims; including one or both of
a waveplate; and
the UV extractor including a α-Barium Borate Oxide birefringent crystal.

17. A device or system according to any of the prior claims, including one or more of:
a Pr:YLF gain media;
a β-Barium Borate Oxide non-linear crystal for second harmonic generation; and
an α-Barium Borate Oxide birefringent crystal.

18. A device or system according to any of the prior claims, including one or more of:
an air gap between the first mirror and the gain media;
an air gap between the NLC and the second mirror;
an air gap between the gain media and the birefringent crystal.

19. A device or system according to claim 18, the gain media and birefringent crystal having anti-reflection coatings on the surfaces exposed to the air gap.

20. A device or system according to any of the prior claims, the birefringent being of a larger dimension than the body of the combination structure.

21. A device or system according to any of the prior claims, the birefringent crystal extending beyond the body of the combination structure.

22. A device or system according to any of claim 20 or 21, the UV light exiting the birefringent crystal at surface of birefringent crystal that is extended or protruding from the body of the combination structure.

23. A device or system according to any of the prior claims, the combination structure further comprising an intra-cavity etalon.

24. A device or system according to claim 22, the etalon positioned between the gain media and the birefringent crystal.

25. A device or system according to claim 23, further comprising emitting only frequency from the device or system.

26. A device or system according to any of the prior claims further comprising a piezo-electrical transducer (PZT).

27. A device or system according to claim 24, the piezo-electrical transducer being one or more of:
mounted to the first mirror, and/or
communicably connected to the first mirror.

28. A device or system according to claim 24 or 25, the PZT obtaining a power feedback signal to select and/or lock in one frequency.

29. A device or system according to claim 24, the piezo-electrical transducer being one or more of:
mounted to the second mirror, and/or
communicably connected to the second mirror.

30. A device or system according to claim 24 or 27, the PZT obtaining a power feedback signal to select and/or lock in one frequency.

31. A device or system according to any of the prior claims, including one or more of:
a prism located external of the combination structure,
a partially transmitting prism, and
a UV detector located external of the combination structure.

32. A device or system according to claim 31, the UV detector positioned behind the partially transmitting prism.

33. A device or system according to claim 4, the combination structure having a length of about 20 mm, 30 mm, or 40 mm.

34. A device or system according to any of the prior claims producing a UV light output.

35. A device or system according to claim 34:
the NLC (or SHG crystal) converting a fundamental light to the UV light output,
the intracavity BC separating the UV light output,
the UV light output deviating from the pump light by a distance (d).

36. A device or system according to any of the prior claims, the NLC acting as a waveplate.

37. A device or system according to any of the prior claims, the NLC functioning for Type 1 and/or Type II second harmonic generation.

38. A device or system according to any of the prior claims, the NLC being temperature tuned to optimize the laser performance.

39. A device or system according to any of the prior claims, the UV light being separated by an intra-cavity polarizing prism.

40. A device or system according to claim 40, the UV light reflecting out of the interface inside the polarizing prism.

41. A device or system according to any of the prior claims, the gain media, the birefringent crystal or polarizing prism, and NLC are optically bonded.

42. A device or system according to any of the prior claims, further comprising:
optically bonding the first mirror to the gain media, or
fabricating the first mirror on the gain media.

43. A device or system according to any of the prior claims, further comprising:
optically bonding the second mirror to the NLC, or
fabricating the second mirror on the NLC.

44. A device or system according to any of the prior claims, further comprising using a VBG to narrow the diode laser emission spectrum.

45. A UV laser comprising:
a pump source having a 444 nm diode laser, a first lens, a volume Bragg grating, and a second lens that produces a pump light;
two or more mirrors defining the structure;
a gain media comprised of Pr:YLF;
a non-linear crystal comprised of a material selected from Beta Barium Borate Oxide, Bismuth Borate Oxide (BiBO), walk-off compensated BBO, walk-off compensated BiBO, lithium triborate oxide (LBO) for second harmonic generation; and
a polarization controller and UV separator.

46. A UV laser comprising:
a pump source;
a monolithic structure having two ends and a length (L) comprising:
two mirrors defining the structure, each mirror disposed at an end of the structure;
a Pr:YLF gain media;
a α-Barium Borate Oxide non-linear crystal for second harmonic generation; and
a β-Barium Borate Oxide birefringent crystal.

47. A UV laser comprising:
a light source;
a monolithic structure having two ends and a length (L) comprising:
two mirrors defining the structure, each mirror operably disposed at an end of the structure;
a Pr:YLF gain media;
a β-Barium Borate Oxide non-linear crystal for second harmonic generation; and
a polarizer prism for separating UV light from the light source.

48. A UV laser comprising:
a light source;
a monolithic structure having two ends and a length (L) comprising:
two mirrors defining the structure, each mirror operably disposed at an end of the structure;
a Pr:YLF gain media;
a non-linear crystal selected from the group of periodically-poled Lithium Niobate (PPLN) and periodically-poled Lithium Tantalate (PPLT);
a waveplate; and
a α-Barium Borate Oxide birefringent crystal.

49. A UV laser comprising:
a light source;
a monolithic structure having two ends and a length (L) comprising:
two mirrors defining the structure, each mirror operably disposed at an end of the structure;
a Pr:YLF gain media;
a non-linear crystal selected from the group of Bismuth Borate Oxide (BiBO), walk-off compensated BBO, walk-off compensated BiBO, and lithium triborate oxide (LBO).
a waveplate; and
a α-Barium Borate Oxide birefringent crystal.

50. A UV laser comprising:
a light source;
a monolithic structure having two ends and a length (L) comprising:
two mirrors defining the structure, each mirror operably disposed at an end of the structure;
a Pr:YLF gain media;
a β-Barium Borate Oxide non-linear crystal for second harmonic generation; and
a an α-Barium Borate Oxide birefringent crystal.

51. A device or system for generating a UV laser, the device or system comprising:
a source of pumping light;
a combination structure comprising:
two or more mirrors,
a gain medium to convert pumping light into lasing light of the fundamental wavelength;
a non-linear crystal disposed to be a secondary harmonic generator (SHG);
a UV extractor;
the combination structure being disposed such that the pumping light from the source of pumping light enters at the first mirror, the gain media absorbs the pumping light and produces the lasing light of the fundamental wavelength between the first and second mirrors; the non-linear crystal converts the lasing light to UV light, and the UV extractor extracts and exits the UV light from the combination structure.

52. A device or system according to claim 51 or any of the prior claims, the UV extractor being:
a polarization controller, and
one of:
a UV separator, or
a birefringent crystal,
the UV extractor separating the UV light from the lasing light of the fundamental wavelength.

53. A device or system according to any of the prior claims, the pump source having:
a 444 nm diode laser,
light delivery optics,
the light delivery optics having any of:
a simple lens that delivers the pump light;
the combination of a first lens, a volume Bragg grating, and a second lens that narrows the pump wavelength and delivers the pump light.

54. A device or system according to any of the prior claims, the UV extractor including a polarization controller and UV separator.

55. A device or system according to any of the prior claims including both of:
the non-linear crystal being a β-Barium Borate Oxide non-linear crystal for second harmonic generation; and,
the UV extractor being an α-Barium Borate Oxide birefringent crystal.
